(19) United States
(12) Patent Application Publication
(10) Pub. No.: US 2013/0146130 A1
(43) Pub. Date: Jun. 13, 2013

(54) CROSS-LINKABLE EDGE SEALANT FOR PHOTOVOLTAIC MODULES

(71) Applicant: E. I. Du Pont De Nemours and Company, Wilmington, DE (US)

(72) Inventors: David D. Zhang, Wilmington, DE (US); George Wyatt Prejean, Orange, TX (US); Jiawei Zhang, Shanghai (CN); Minji Zhao, Shanghai (CN); Kevin J. Leary, Middletown, DE (US)

(73) Assignee: E. I. Du Pont De Nemours and Company, Wilmington (DE)

(21) Appl. No.: 13/709,754

(22) Filed: Dec. 10, 2012

(30) Foreign Application Priority Data
Dec. 9, 2011 (CN) 201110408208.3

(51) Int. Cl. H01L 31/048; H01L 31/0203

(52) U.S. Cl. CPC H01L 31/0481; H01L 31/0203
USPC 136/251; 438/64

(57) ABSTRACT

A framed solar cell module comprises: (a) a platelike solar cell module that comprises a solar cell element formed of one or a plurality of electrically interconnected solar cells; (b) a frame body that has a groove portion into which the outer periphery of the solar cell module is fitted; and (c) a sealant material that is so provided as to fill up a space between the outer periphery of the solar cell module and the groove portion of the frame body, and wherein the sealant material is formed of a cross-linkable blend composition of an ionomer and an ethylene copolymer.

### CROSS-REFERENCE TO RELATED APPLICATION

This application claims priority under 35 U.S.C. §119(a) to Patent Application for Invention No. 201110408208.3, filed in the State Intellectual Property Office of the People's Republic of China on Dec. 9, 2011, which is incorporated herein by reference in its entirety.

### FIELD OF THE INVENTION

The disclosure is related to framed solar cell modules using a novel edge seal material.

### BACKGROUND OF THE INVENTION

Several patents and publications are cited in this description in order to more fully describe the state of the art to which this invention pertains. The entire disclosure of each of these patents and publications is incorporated by reference herein.

Currently, silicone glues are often used as the edge seal material to bond the aluminum frames around solar cell modules. Using silicone glue as the edge seal material has a number of drawbacks. First, after silicone glue is applied, excess residues are often left on the module surfaces and need to be wiped away. This not only causes higher manufacturing cost, but also causes environment issues. Secondly, prolonged (at least about 6 hours) curing time is required for silicone glue and therefore the production efficiency is reduced. Moreover, butanone oxime is often released when silicone glue is used and therefore causes odor issue. Finally, the excessive waste that is generated when silicone glue is used also causes higher manufacturing cost. Thus, there is still a need to develop a new edge seal material that is environmentally friendly, cost effective, easy to handle, and that requires shorter curing time.

### SUMMARY OF THE INVENTION

Provided herein is a framed solar cell module comprising:
(a) a platelike solar cell module comprising a solar cell element formed of one or a plurality of electrically interconnected solar cells;
(b) a frame body having a groove portion, into which the outer periphery of the solar cell module is fitted; and
(c) a sealant material so provided as to fill up a space between the outer periphery of the solar cell module and the groove portion of the frame body, the sealant material being formed of a cross-linkable blend composition containing 10-90 wt % of an ionomer and 10-90 wt % of an ethylene copolymer,

with the total wt % of all the components comprised in the cross-linkable blend composition totaling to 100 wt %, and wherein,
(i) the ionomer is derived from a precursor acid copolymer consisting essentially of copolymerized units of ethylene, optionally up to 40 wt % of copolymerized units of a first olefin having a formula of CH₂═C(R¹)CO₂R², and 2-30 wt % of copolymerized units of a second olefin having a formula of CH₂═C(R³)COOH, with the total wt % of all the copolymerized units comprised in the precursor acid copolymer totaling to 100 wt %, wherein R¹ is hydrogen or an alkyl group, R² is an alkyl group, and R³ is hydrogen or an alkyl group, and wherein at least a portion of the carboxylic acid groups of the precursor acid copolymer is neutralized by one or more cations to form the ionomer;
(ii) the ethylene copolymer consists essentially of copolymerized units of ethylene, optionally up to 40 wt % of copolymerized units of the first olefin, and 3-15 wt % of copolymerized units of a third olefin having a formula of CH₂═C(R⁴)-D, with the total wt % of all the copolymerized units comprised in the ethylene copolymer totaling to 100 wt %, and with R⁴ being hydrogen or an alkyl group and -D being a moiety selected from the group consisting of —CO₂R⁵, —CO₂R⁶—R⁵, —R⁶—R⁵, —O—R⁵, and —R⁵, and with R⁵ being a moiety containing an epoxy group and R⁶ being an alkylene group; and
(iii) none of the first, second or third olefin is a dicarboxylic acid or a di-ester, mono-ester or anhydride of the dicarboxylic acid.

In one embodiment of the framed solar cell module, the sealant material is formed of a product of cross-linking the cross-linkable blend composition described above. In this cross-linked product, at least a portion of the carboxylic acid groups comprised in the Ethylene Copolymer-1 are reacted with at least a portion of the epoxy groups comprised in the Ethylene Copolymer-2 to form cross-links between the Ethylene Copolymer-1 and the Ethylene Copolymer-2.

In a further embodiment of the framed solar cell module, the weight ratio of the ionomer and the ethylene copolymer comprised in the cross-linkable blend composition ranges from 80:20 to 20:80, or from 70:30 to 30:70; or from 60:40 to 40:60.

In a yet further embodiment of the framed solar cell module, the first olefin is selected from the group consisting of methyl acrylate, methyl methacrylate, ethyl acrylate, ethyl methacrylate, butyl acrylate, and butyl methacrylate, or the first olefin is selected from the group consisting of n-butyl acrylate, iso-butyl acrylate, methyl methacrylate, and n-butyl methacrylate.

In a yet further embodiment of the framed solar cell module, the second olefin is an acrylic acid or a methacrylic acid.

In a yet further embodiment of the framed solar cell module, the moiety R⁵ is a glycidyl group, a 1,2-cyclohexenyl oxide group, or a 1,2-epoxy group.

In a yet further embodiment of the framed solar cell module, the precursor acid copolymer of the ionomer comprises 5-40 wt %, or 10-35 wt %, or 10-30 wt % of copolymerized units of the first olefin, with the total wt % of all the copolymerized units comprised in the precursor acid copolymer totaling to 100 wt %.

In a yet further embodiment of the framed solar cell module, the precursor acid copolymer of the ionomer comprises 5-20 wt % or 5-15 wt % of copolymerized units of the second olefin, with the total wt % of all the copolymerized units comprised in the precursor acid copolymer totaling to 100 wt %.

In a yet further embodiment of the framed solar cell module, the precursor acid copolymer of the ionomer has a melt flow rate of 5 g/10 min or higher, or 30 g/10 min or higher, or 30-500 g/10 min, as determined in accordance with ASTM D1238 at 190° C. and under a weight of 2.16 kg.

In a yet further embodiment of the framed solar cell module, 10-90%, or 15-60%, or 15-40% of the carboxylic acid groups of the precursor acid copolymer is neutralized to form the ionomer, which comprises carboxylate groups and one or more cations.

In a yet further embodiment of the framed solar cell module, the one or more cations are selected from Na+ cation, Zn²⁺ cation, and combinations thereof.

In a yet further embodiment of the framed solar cell module, the ionomer has a melt flow rate of 1 g/10 min or higher, or 2-500 g/10 min, or 4-500 g/10 min, as determined in accordance with ASTM D1238 at 190° C. and under a weight of 2.16 kg.

In a yet further embodiment of the framed solar cell module, the ionomer is a zinc ionomer that is derived from a precursor acid copolymer of ethylene /methacrylic acid.

In a yet further embodiment of the framed solar cell module, the ethylene copolymer comprises 3-10 wt % or 4-7 wt % of copolymerized units of the third olefin, with the total wt % of all the copolymerized units comprised in the ethylene copolymer totaling to 100 wt %.

In a yet further embodiment of the framed solar cell module, the ethylene copolymer comprises 5-40 wt %, or 10-40 wt %, or 20-40 wt %, or 20-35 wt % of copolymerized units of the first olefin, with the total wt % of all the copolymerized units comprised in the ethylene copolymer totaling to 100 wt %.

In a yet further embodiment of the framed solar cell module, the ethylene copolymer has a melt flow rate of 5-300 g/10 min or 5-100 g/10 min, as determined in accordance with ASTM D1238 at 190° C. and under a weight of 2.16 kg.

In a yet further embodiment of the framed solar cell module, the ethylene copolymer is a copolymer of ethylene/n-butyl acrylate/glycidyl methacrylate.

In a yet further embodiment of the framed solar cell module, the frame body is formed of a metallic material or a plastic material.

Further provided herein is a method for preparing a framed solar cell module, comprising the steps of:
(a) providing a platelike solar cell module comprising a solar cell element formed of one or a plurality of electrically interconnected solar cells;
(b) providing a frame body having a groove portion;
(c) providing a sealant material formed of the cross-linkable blend composition described above; and
(d) attaching the outer periphery of the solar cell module into the inside of the groove portion of the frame body, with the sealant material filling up the space between the outer periphery of the solar cell module and the frame body, to obtain the framed solar cell module.

In one embodiment of the method for preparing the framed solar cell module, step (d) comprises: (i) attaching a polymer strip formed of the sealant material around the outer periphery of the solar cell module; and (ii) attaching the outer periphery of the solar cell module, which is covered by the polymer strip, into the inside of the groove portion of the frame body.

In a further embodiment of the method for preparing the framed solar cell module, step (d) comprises: (i) attaching a polymer strip formed of the sealant material over the inside of the groove portion of the frame body; and (ii) attaching the outer periphery of the solar cell module into the inside of the groove portion of the frame body, which is covered by the polymer strip.

In a yet further embodiment of the method for preparing the framed solar cell module, step (d) comprises: (i) extrusion coating the sealant material around the outer periphery of the solar cell module; and (ii) attaching the outer periphery of the solar cell module, which is extrusion coated with the sealant material, into the inside of the groove portion of the frame body.

In a yet further embodiment of the method for preparing the framed solar cell module, step (d) comprises: (i) extrusion coating the sealant material over the inside of the groove portion of the frame body; and (ii) attaching the outer periphery of the solar cell module into the inside of the groove portion of the frame body, which is extrusion coated with the sealant material.

In a yet further embodiment of the method for preparing the framed solar cell module, the method further comprises step (e) subjecting the framed solar cell module obtained in step (d) to curing at a temperature of 135° C. or higher, or to 140° C.-180° C. In step (e), the curing duration may be 5-60 minutes, or 5-30 minutes, or 5-20 minutes.

Further provided herein is a method for preparing a plastic framed solar cell module, comprising the steps of:
(a) providing a platelike solar cell module comprising a solar cell element formed of one or a plurality of electrically interconnected solar cells;
(b) co-extruding a polymer composition and the cross-linkable blend composition described above to form a frame body, wherein the frame body has a groove portion and the inside layer of the groove portion is formed of the cross-linkable blend composition; and
(c) attaching the outer periphery of the solar cell module into the inside of the groove portion of the frame body.

In one embodiment of the method for preparing the plastic framed solar cell module, the method further comprises step (d) subjecting the framed solar cell module obtained in step (c) to curing at a temperature of 135° C. or higher, or to 140° C.-180° C. In step (d), the curing duration may be 5-60 minutes, or 5-30 minutes, or 5-20 minutes.

These and various other advantages and features of novelty that characterize the invention are pointed out with particularity in the claims annexed hereto and forming a part hereof. For a better understanding of the invention, its advantages, and the objects obtained by its use, however, reference should be made to the drawings which form a further part hereof, and to the accompanying descriptive matter, in which there is illustrated and described a preferred embodiment of the invention.

### BRIEF DESCRIPTION OF THE DRAWINGS

FIG. 1 is a not-to-scale cross-sectional view of one embodiment of the framed solar cell module disclosed herein.

FIG. 2 depicts one embodiment of the process for preparing the framed solar cell module disclosed herein.

FIG. 3 depicts a further embodiment of the process for preparing the framed solar cell module disclosed herein.

FIG. 4 depicts a yet further embodiment of the process for preparing the framed solar cell module disclosed herein.

FIG. 5 depicts a yet further embodiment of the process for preparing the framed solar cell module disclosed herein.

FIG. 6 depicts a yet further embodiment of the process for preparing the framed solar cell module disclosed herein.

### DETAILED DESCRIPTION OF THE INVENTION

The following definitions apply to the terms as used throughout this specification, unless otherwise limited in specific instances.

Unless otherwise defined, all technical and scientific terms used herein have the same meaning as commonly understood by one of ordinary skill in the art to which this invention belongs. In case of conflict, the specification, including definitions, will control.

When a composition, a process, a structure, or a portion of a composition, a process, or a structure, is described herein using an open-ended term such as “comprising,” unless otherwise stated the description also includes an embodiment that “consists essentially of” or “consists of” the elements of the composition, the process, the structure, or the portion of the composition, the process, or the structure.

The term “or”, as used herein, is inclusive; that is, the phrase “A or B” means “A, B, or both A and B”. More specifically, a condition “A or B” is satisfied by any one of the following: A is true (or present) and B is false (or not present); A is false (or not present) and B is true (or present); or both A and B are true (or present). Exclusive “or” is designated herein by terms such as “either A or B” and “one of A or B”, for example.

In addition, the ranges set forth herein include their endpoints unless expressly stated otherwise. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. The scope of the invention is not limited to the specific values recited when defining a range.

As used herein, the term “copolymer” refers to polymers comprising copolymerized units resulting from copolymerization of two or more comonomers. In this connection, a copolymer may be described herein with reference to its constituent comonomers or to the amounts of its constituent comonomers, for example “a copolymer comprising ethylene and 18 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

The terms “epoxy group”, “ethylene oxide group” and “oxirane ring” are synonymous and used interchangeably herein to refer to a substituted or unsubstituted group having the formula —CROCR2, wherein the oxygen atom is bound to both carbons and the carbons are bound to each other. When the R groups are hydrogen atoms, the ethylene oxide group is unsubstituted. The ethylene oxide group may be singly or multiply substituted. Stated alternatively, one, two or three of the R groups may be other than hydrogen atoms.

The terms “alkyl group” and “alkylene group”, as used herein alone or in combined form, such as, for example, “alkoxy group”, refer to saturated hydrocarbon groups that have from 1 to 8 carbon atoms and that may be branched or unbranched. An alkyl group has one bond to a carbon atom available for substitution, and an alkylene group has two bonds to one or more carbon atoms available for substitution.

Finally, the term “solar cell” as used herein includes any article which can convert light into electrical energy. Solar cells useful in the invention include, but are not limited to, wafer-based solar cells (e.g., c-Si or mc-Si based solar cells), thin film solar cells (e.g., a-Si, μc-Si, CdTe, or CI(G)S based solar cells), and organic solar cells.

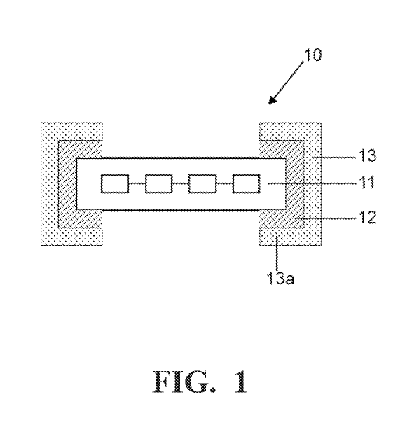

Referring now to the drawings, wherein like reference letters and numerals designate corresponding structure throughout the views, and referring in particular to FIG. 1, provided herein is a framed solar cell module (10) comprising: (a) a platelike solar cell module (11) that comprises a solar cell element formed of one or a plurality of electrically interconnected solar cells; (b) a frame body (13) that has a groove portion (13a) into which the outer periphery of the solar cell module (11) is fitted; and (c) a sealant material (or edge seal material) (12) that is so provided as to fill up a space between the outer periphery of the solar cell module (10) and the groove portion (13a) of the frame body (13), and wherein the sealant material (12) is formed of a cross-linkable blend composition such as that disclosed in U.S. patent application Ser. No. 12/847,293. Within the framed solar cell module (10), the solar cell module (11) and frame body (13) are bonded by the sealant material (12) that is positioned therebetween. In addition, the sealant material (12) also serves as a moisture barrier for the framed module (10).

More specifically, the cross-linkable blend composition used herein comprises about 10-90 wt % of an ionomer and about 10-90 wt % of an ethylene copolymer, with the total wt % of all the components comprised in the blend composition totaling to 100 wt %.

The ionomer comprised in the blend composition is derived from an precursor acid copolymer consisting essentially of copolymerized units of ethylene, optionally up to about 40 wt % of copolymerized units of a first olefin having a formula of CH₂═C(R¹)CO₂R², and about 2-30 wt % of copolymerized units of a second olefin having a formula of CH₂═C(R³)COOH, with the total wt % of all the copolymerized units comprised in the precursor acid copolymer totaling to 100 wt %, and with R¹ representing hydrogen or an alkyl group, R² representing an alkyl group, and R³ representing hydrogen or an alkyl group, and wherein the ionomer is prepared by neutralizing at least a portion of the carboxylic acid groups of the precursor acid copolymer by one or more cations.

Ionomers and methods of synthesizing ionomers have been described at length elsewhere, for example U.S. Pat. No. 5,028,674, and U.S. patent application Ser. No. 12/610,678, filed on Nov. 2, 2009, and the references cited therein. To obtain the ionomers used herein, the precursor acid copolymers may be neutralized by any conventional procedure, such as those described in U.S. Pat. Nos. 3,404,134 and 6,518,365.

The ethylene copolymer comprised in the blend composition consists essentially of copolymerized units of ethylene, optionally up to about 40 wt % of copolymerized units of the first olefin, and about 3-15 wt % of copolymerized units of a third olefin having a formula of CH₂═C(R⁴)-D, with the total wt % of all the copolymerized units comprised in the ethylene copolymer totaling to 100 wt %, and with R⁴ representing hydrogen or an alkyl group and -D representing a moiety selected from the group consisting of —CO₂R⁵, —CO₂R⁶—R⁵, —R⁶—R⁵, —O—R⁵, and —R⁵, and with R⁵ being a moiety containing an epoxy group and R⁶ being an alkylene group.

In addition, it is understood that none of the first, second, or third olefins used herein is a dicarboxylic acid or a di-ester, mono-ester or anhydride of the dicarboxylic acid.

Suitable first olefins having the formula CH₂═C(R¹)CO₂R² include, without limitation, methyl acrylate, methyl methacrylate, ethyl acrylate, ethyl methacrylate, butyl acrylate, and butyl methacrylate. Preferably, the first olefin is selected from n-butyl acrylate, iso-butyl acrylate, methyl methacrylate, and n-butyl methacrylate. Suitable second olefins having the formula CH₂═C(R³)COOH include, without limitation, acrylic acids and methacrylic acids. In addition, in the third olefin of formula CH₂═C(R⁴)-D, the moiety R⁵ that is comprised in D is a moiety containing an epoxy group, such as a glycidyl group, a 1,2-cyclohexenyl oxide group, or a 1,2-epoxy group.

Preferred neutralization levels are about 10-90%, about 15-60%, or about 15-40%. Neutralization level is expressed as the weight percentage of the acid present in the ionomer that is neutralized. For example, if the ionomer contains 15 wt % of methacrylic acid and the neutralization level is 25%, then 3.75 wt % of the acid groups are neutralized, based on the total weight of the copolymer.

In addition, the ionomer used herein has a melt flow rate (MFR) of about 1 g/10 min or higher, or about 2-500 g/10 min, or about 4-500 g/10 min, as determined in accordance with ASTM D1238 at 190° C. and under a weight of 2.16 kg.

Any stable cation and any combination of two or more stable cations are believed to be suitable as counterions to the carboxylate groups in the ionomer. Divalent cations, such as cations of alkaline earth metals and some transition metals, are preferred. Zinc is a preferred divalent cation. Still more preferably, the ionomer used herein is a zinc ionomer in which about 10-90%, about 15-60%, or about 15-40% of the hydrogen atoms of the carboxylic acid groups of the precursor acid copolymers are replaced by a charge-equivalent amount of zinc cations.

In addition, the ionomer used herein may optionally further comprise other suitable additional comonomers, such as unsaturated carboxylic acids having 2 to 10, or preferably 3 to 8 carbons, or derivatives thereof. Suitable acid derivatives include acid anhydrides, amides, and esters. However, the ionomer preferably does not incorporate the other additional comonomers in any significant amount. In one embodiment, the precursor acid copolymer of the ionomer used herein comprises about 5-40 wt %, or about 10-35 wt %, or about 10-30 wt % of copolymerized units of the first olefin of formula CH₂═C(R¹)CO₂R², when the first olefin is present. The precursor acid copolymer of the ionomer used herein further comprises about 2-30 wt %, or about 5-20 wt %, or about 5-15 wt % of copolymerized units of the second olefin of the formula CH₂═C(R³)COOH. The remainder of the precursor acid copolymer of the ionomer used herein comprises copolymerized units of ethylene and up to about 5 wt % of optional additional comonomers. These weight percentages are based on the total weight of the precursor acid copolymer of the ionomer used herein. Moreover, the precursor acid copolymer of the ionomer used herein, prior to neutralization, may have a melt flow rate of about 5 g/10 min or higher, or about 30 g/10 min or higher, or about 30-500 g/10 min, as determined in accordance with ASTM D1238 at 190° C. and under a weight of 2.16 kg.

Ionomers suitable for use herein also may be obtained commercially. For example, the ionomer used herein may be available from E. I. du Pont de Nemours and Company, Wilmington, Del. (“DuPont”) under the trademark Surlyn®.

The ethylene copolymer comprised in the blend composition also may optionally further comprise other suitable additional comonomers, as described above with respect to the precursor acid copolymer of the ionomer used herein. Preferably, however, the ethylene copolymer used herein does not incorporate the other additional comonomers in any significant amount. In one embodiment, the ethylene copolymer comprises about 3-15 wt %, or about 3-10 wt %, or about 4-7 wt % of copolymerized units of the third olefin of the formula CH₂═C(R⁴)-D. It may optionally further comprise up to about 40 wt %, or about 5-40 wt %, or about 10-40 wt %, or about 20-40 wt %, or about 20-35 wt % of copolymerized units of the first olefin of the formula CH₂═C(R¹)CO₂R². The remainder of the ethylene copolymer comprises copolymerized units of ethylene and up to about 5 wt % of optional additional comonomers. These weight percentages are based on the total weight of ethylene copolymer. The ethylene copolymer may have a melt flow rate of about 5-300 g/10 min or about 5-100 g/10 min, as determined in accordance with ASTM D1238 at 190° C. and under a weight of 2.16 kg. Ethylene copolymers suitable for use herein also may be obtained commercially. For example, the ethylene copolymer used herein may be a copolymer of ethylene/n-butyl acrylate/glycidyl methacrylate, such as those available from DuPont under the trademark Elvaloy®.

Within the cross-linkable blend composition, the ratio of the ionomer and the ethylene copolymer may range from about 90:10 to about 10:90, or about 80:20 to about 20:80, or about 70:30 to about 30:70, or about 60:40 to about 40:60, by weight. In addition, the mole ratio of the carboxylic acid groups comprised in the precursor acid copolymer of the ionomer to the epoxy groups comprised in the ethylene copolymer is preferably about 10:1 to about 1:10, about 5:1 to about 1:5, about 3:1 to about 1:3, or about 2:1 to about 1:2.

In addition to the ionomer and the ethylene copolymer, the cross-linkable blend composition may further include one or more suitable additive(s) that are known in the art. Such additives include, but are not limited to, processing aids, catalysts, flow enhancing additives, lubricants, pigments, dyes, optical brighteners, flame retardants, impact modifiers, nucleating agents, anti-blocking agents (e.g., silica), thermal stabilizers, hindered amine light stabilizers (HALS), UV absorbers, UV stabilizers, dispersants, surfactants, chelating agents, coupling agents, adhesives, primers, reinforcement additives (e.g., calcium carbonate), and combinations of two or more thereof. Suitable additives may be present in the cross-linkable blend composition at a level of about 0.01-15 wt %, or about 0.01-10 wt %, or about 0.01-5 wt %, or about 0.01-1 wt %, in total, based on the total weight of the cross-linkable blend composition.

As is set forth in detail in U.S. patent application Ser. No. 12/847,293, the cross-linkable blend composition of the ionomer and the ethylene copolymer can be prepared by any suitable process, such as melt blending or dry blending. Preferably, during the melt blending processes, the process temperature is maintained at or below about 135° C., or at or below about 130° C., or at or below about 125° C., or at or below about 120° C., to prevent premature cross-linking.

The platelike solar cell module (11) used herein comprises a solar cell element that is formed of one or a plurality of electrically interconnected solar cells. The solar cells used herein may be any article or material that can convert light into electrical energy. Solar cells useful herein include, without limitation, wafer-based solar cells (e.g., monocrystalline silicon (c-Si) or multi-crystalline silicon (mc-Si) based solar cells) and thin film solar cells (e.g., amorphous silicon (a-Si), microcrystalline silicon (μc-Si), cadmium telluride (CdTe), copper indium selenide (CIS), copper-indium-gallium selenide (CIGS), light absorbing dyes, or organic semiconductor based solar cells). Within the solar cell element, the solar cells are electrically interconnected or arranged in a flat plane. In addition, the solar cell element may further comprise electric wirings, such as cross ribbons and bus bars.

The solar cell elements may be bifacial. In such embodiments, all the laminating materials positioned on either side of the solar cell elements should be sufficiently transparent to allow adequate sunlight or reflected sunlight to reach the solar cells. Alternatively, the solar cell elements may have a front sun-facing side (which is also referred to as a front side and, when in actual use conditions, generally faces toward the sun) and a back non-sun-facing side (which is also referred to as a back side and, when in actual use conditions, generally faces away from the sun). The solar cells define the boundary between the front and back sides of the solar cell elements. In such embodiments, all the materials that are present in the laminate layers positioned to the front sun-facing side of the solar cell elements should have sufficient transparency to allow adequate sunlight to reach the solar cells. While the materials present in the laminate layers positioned to the back non-sun-facing side of the solar cell elements need not be transparent.

In addition to the solar cell element, a solar cell module may further comprise encapsulant layer(s) laminated to one or both sides of the solar cell element. The encapsulant layers may be formed of any suitable polymeric materials, such as acid copolymers, ionomers (same or different from the ionomers comprised in the blend composition disclosed herein), ethylene/vinyl acetate copolymers (EVA), poly(vinyl acetals) (e.g., poly(vinyl butyral) (PVB)), polyurethanes, poly(vinyl chlorides), polyethylenes (e.g., linear low density polyethylenes), polyolefin block copolymer elastomers, copolymers of α-olefins and α,β-ethylenically unsaturated carboxylic acid esters (e.g., ethylene methyl acrylate copolymers and ethylene butyl acrylate copolymers), silicone elastomers, epoxy resins, and combinations of two or more thereof. Moreover, the encapsulant layers may also be formed of the cross-linkable blend composition disclosed herein.

Further, the solar cell module may further comprise an incident layer or a backing layer serving as the outermost layer or layers of the module at the sun-facing side and the non-sun-facing side of the solar cell module, respectively. The incident layer and the backing layer may comprise any suitable sheet or film. Suitable sheets include, for example, glass or plastic sheets, such as polycarbonates, acrylics, polyacrylates, cyclic polyolefins (e.g., ethylene norbornene polymers), polystyrenes (preferably polystyrenes prepared in the presence of metallocene catalysts), polyamides, polyesters, fluoropolymers, or combinations of two or more thereof. In addition, metal sheets, such as aluminum, steel, galvanized steel, or ceramic plates may be used in the backing layer.

Suitable films useful as the incident layer or the backing layer may be formed of any suitable polymeric materials, such as polyesters (e.g., poly(ethylene terephthalate) (PET) and poly(ethylene naphthalate) (PEN)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophane, silicones, poly(vinyl chlorides) (e.g., poly(vinylidene chloride)), fluoropolymers (e.g., polyvinyl fluoride, polyvinylidene fluoride, polytetrafluoroethylene, and ethylene-tetrafluoroethylene copolymers), and combinations of two or more thereof.

Specific examples of films that may be used in the solar cell module outer layers (e.g., the incident layer or the backing layer) include, but are not limited to, polyester films (e.g., poly(ethylene terephthalate) films), fluoropolymer films (e.g., Tedlar®, Tefzel®, and Teflon® films available from DuPont). Metal films, such as aluminum foil, may also be used as the backing layers. Further the films used as the backing layers in solar cell modules may be in the form of multi-layer films, such as a fluoropolymer/polyester/fluoropolymer multilayer film (e.g., Tedlar®/PET/Tedlar® or TPT laminate backsheet available from Isovolta AG (Austria), or Madico (U.S.A.), or Krempel Group (Germany).

The frame body (13) included herein has a groove portion (13a) into which the outer periphery of the solar cell module (11) is fitted. The frame body (13) may be formed of any suitable material(s). For example, the frame body (13) used herein may be formed of any suitable metal(s), such as aluminum. With the desire to reduce the overall weight of the module (10), plastic materials have also been used in forming the frame bodies (13). Examples of plastic materials suitable for use herein include, without limitation, polyesters (e.g., poly(ethylene terephthalate) (PET), polybutylene terephthalate (PBT), or poly(trimethylene terephthalate) (PTT)), polyamides (PA), polycarbonates (PC), polyphenyloxides (PPO), and blends thereof. Examples of polymer blends suitable for use in forming the frame bodies (13) include, without limitation, blends of polycarbonate and acrylonitrile butadiene styrene (PC/ABS blends), blends of polycarbonate and poly(ethylene terephthalate) (PC/PET blends), blends of polycarbonate and polybutylene terephthalate (PC/PBT blends), blends of polyamide and acrylonitrile butadiene styrene blends (PA/ABS blends). Moreover, various suitable fillers may also be contained in the plastic materials used herein. Examples of fillers suitable for use herein include, without limitation, talc, glass fibers, carbon fibers, ceramic fibers, calcium carbonates, micas, and combinations thereof.

The framed solar cell module (10) disclosed herein may be prepared by any suitable process. In general, the process may include, (i) preparing a frameless solar cell module (11); and (ii) framing the solar cell module (11) by attaching the outer periphery of the solar cell module (11) into the inside of the groove portion (13a) of a frame body (13), with the sealant material (12) filling up the space between the outer periphery of the solar cell module (11) and the frame body (13). The sealant material is the cross-linkable blend composition disclosed above.

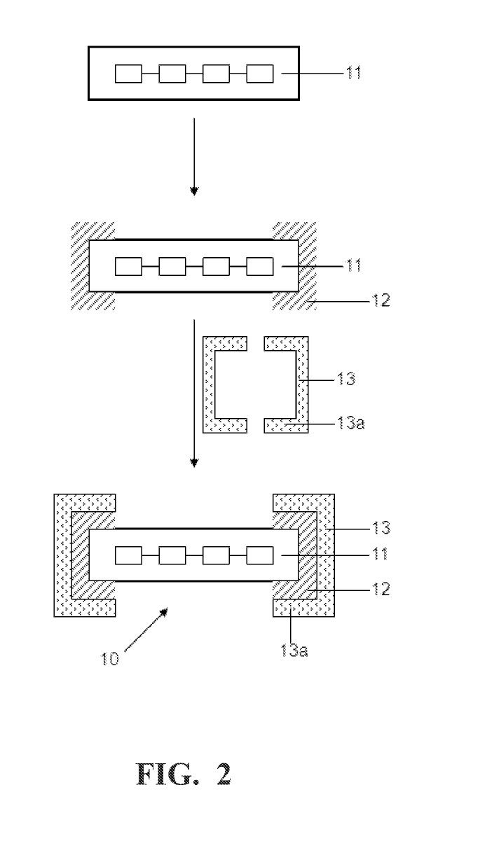

In one embodiment (FIG. 2), the framing step (ii) includes: (a) attaching a polymer strip formed of the cross-linkable blend composition around the outer periphery of the solar cell module (11); and (b) attaching the outer periphery of the solar cell module (11), which is covered by the polymer strip, into the inside of the groove portion (13a) of the frame body (13).

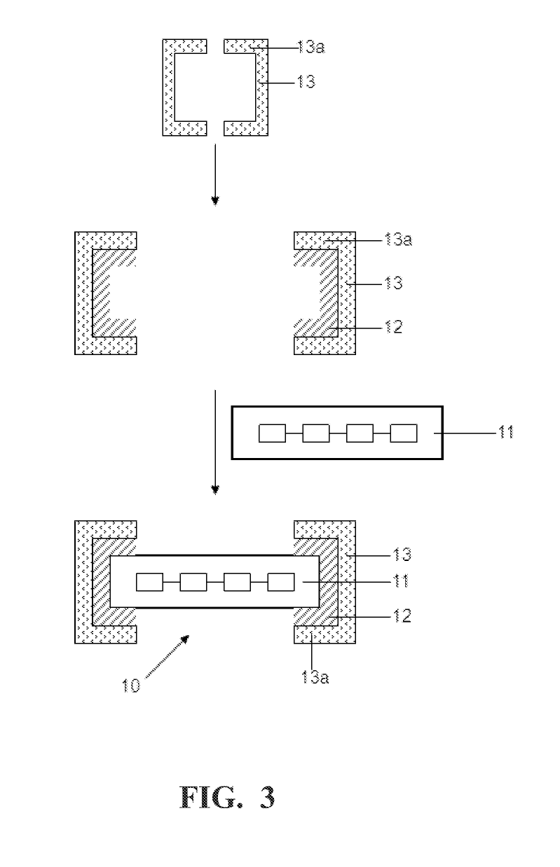

In a further embodiment (FIG. 3), the framing step (ii) includes: (a) attaching a polymer strip formed of the cross-linkable blend composition over the inside of the groove portion (13a) of the frame body (13); and (b) attaching the outer periphery of the solar cell module (11) into the inside of the groove portion (13a) of the frame body (13), which is covered by the polymer strip.

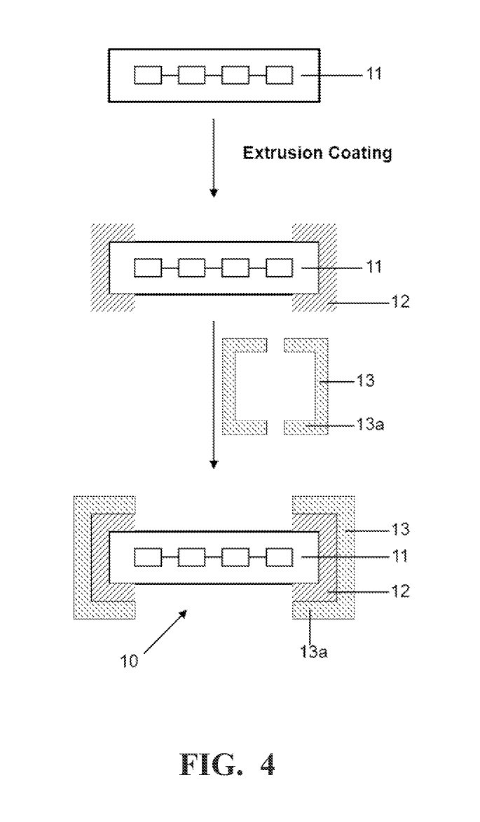

In a yet further embodiment (FIG. 4), the framing step (ii) includes: (a) extrusion coating the cross-linkable blend composition around the outer periphery of the solar cell module (11); and (b) attaching the outer periphery of the solar cell module (11), which is extrusion coated with the cross-linkable blend composition, into the inside of the groove portion (13a) of the frame body (13).

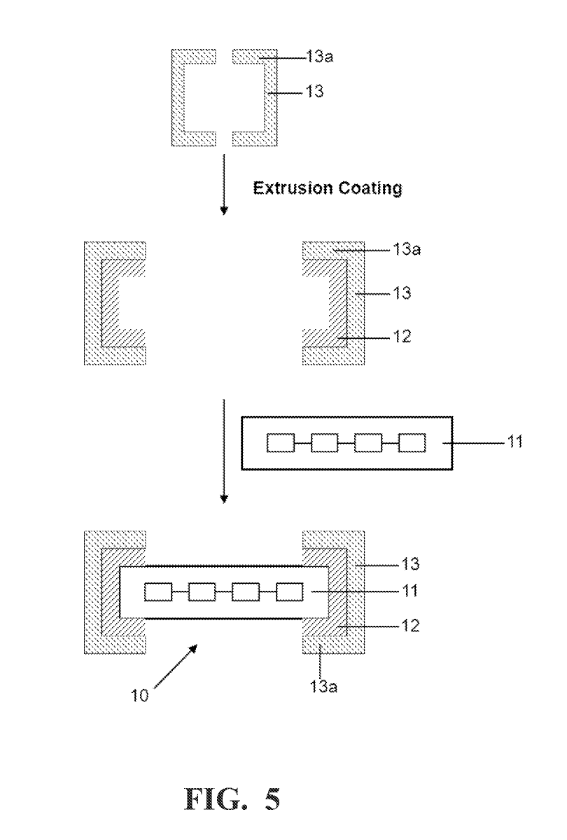

In a yet further embodiment (FIG. 5), the framing step (ii) includes: (a) extrusion coating the cross-linkable blend composition over the inside of the groove portion (13a) of the frame body (13); and (b) attaching the outer periphery of the solar cell module (11) into the inside of the groove portion (13a) of the frame body (13), which is extrusion coated with the cross-linkable blend composition.

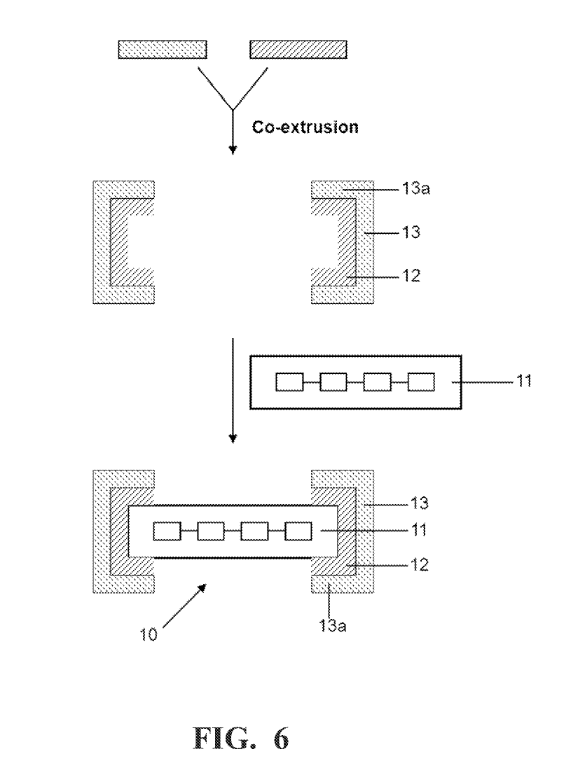

In a yet further embodiment (FIG. 6), the frame body (13) is formed of a plastic material and the framing step (ii) includes: (a) co-extruding a frame body (13), in which the inside layer of the groove portion (13a) of the frame body is formed of the cross-linkable blend composition; and (b) attaching the outer periphery of the solar cell module (11) into the inside of the groove portion (13a) of the frame body (13).

The process may further comprise a curing step (iii), in which the structure that is obtained in the framing step (ii) is cured at a temperature of about 135° C. or higher, or of about 140° C.-180° C. for about 5-60 minutes, or about 5-30 minutes, or about 5-20 minutes. During the curing step (iii), the cross-linkable blend composition is melted and cross-linked. It fills up the space between the frame body (13) and the outer periphery of the solar cell modules (11). By such processes, the sealant material that is comprised in the framed solar cell module (10) disclosed herein is formed of a cross-linked blend composition of the ionomer and the ethylene copolymer. Stated alternatively, within the cross-linked blend composition, cross-links are formed between the ionomer and the ethylene copolymer. Also, as is set forth in detail in U.S. Patent Publication No. US2011/0023943, the cross-links between ionomer and the ethylene copolymer are formed during this high-temperature step, and the rate at which the reaction proceeds depends on one or more of the curing temperature, the melt flow rate of the blend, the concentration of catalyst, if any, and the concentration of the reactive monomers that are present.

Using the cross-linkable blend compositions described herein as the sealant material has a number of advantages over silicone glues. Among them, the cross-linkable blend composition may be made into strips with various profiles by standard thermoplastic extrusion process. Such strips can then be readily applied between the outer periphery of the solar cell module (11) and the groove portion (13a) of the frame body (13) and therefore the framing process may be very much simplified. Further, the time that is required for curing the cross-linkable blend composition (about 30 minutes or so) is much shorter than the time that is required for curing silicone glues (at least about 6 hours). Yet further, when silicone glue is used as the sealant material, excess residues often contaminate the module surfaces after the framing process and an extra cleaning step is therefore necessary after the framing process. However, when the cross-linkable blend composition described herein is used as the sealant material, no or very little excess residues contaminate the module surfaces after the framing process and therefore no extra cleaning step is needed.

The following examples are provided to describe the invention in further detail. These examples, which set forth a preferred mode presently contemplated for carrying out the invention, are intended to illustrate and not to limit the invention.

### EXAMPLES

### Materials:

Cross-linkable Blend Sheet-1 (CBS-1): a 0.5 mm thick polymer sheet that is prepared as follows. First, a dry blend of an ionomer and an ethylene copolymer (60:40 by weight) is prepared in a cement mixer. Then, the dry blend is introduced into a cast film machine (manufactured by Davis Standard) to produce the polymer sheet, wherein the extrusion temperature is set at 120° C. and the line speed at 2 m/min. The ionomer used herein is a sodium ionomer (which has a melt flow rate of 10 g/10 min and is derived from a precursor acid copolymer of ethylene (89 wt %)/methacrylic acid (11 wt %) that is 37% neutralized with Na⁺ cation). The ethylene copolymer used herein is an ethylene/n-butyl acrylate/glycidyl methacrylate copolymer that had a melt flow rate of 12 g/10 min and comprised copolymerized units of ethylene (66.75 wt %), n-butyl acrylate (28 wt %), and glycidyl methacrylate (5.25 wt %);
Cross-linkable Blend Sheet-2 (CBS-2): a 0.5 mm thick polymer sheet that is prepared similarly as CBS-1 with the exception that the ionomer used is a zinc ionomer (which has a melt flow rate of 14 g/10 min and is derived from a precursor acid copolymer of ethylene (85 wt %)/methacrylic acid (15 wt %) that is 22% neutralized with Zn²⁺ cation);
Silicone Glue: TONSAN 1527 silicone sealant (for use in solar cell panels) that may be obtained from Beijing Tonsan Adhesive Inc. (China);
Glass Sheet: 170×150×2 mm glass sheets that may be obtained from Suzhou Qinghua Guangxue Jingpian Co., Ltd. (China);
EVA Sheet: 0.45 mm thick Revax™ ethylene vinyl acetate (EVA) sheet that may be obtained from Wenzhou Ruiyang Photovoltaic Material Co. Ltd. (China);
Solar Cell: monocrystalline silicon solar cells that may be obtained from JA Solar Holdings Co., Ltd. (China), with a Product ID of 125SOR22B;
TPT Sheet: 0.32 mm thick laminated backsheets that may be obtained from Krempel Group under the trade name AKASOL™ PTL3;
Aluminum Frame Bars: pre-formed aluminum framing materials having a length of 172 mm or 152 mm, which may be obtained from Jiangyin GuangYue Solar Science&Technology Co., Ltd, (China).

### Examples E1-E2

First, solar cell modules with the structure of “Glass Sheet/EVA Sheet/Solar Cell/EVA Sheet/TPT Sheet” are prepared by processing the assembly in a vacuum laminator (Model Meier Icolam 10/08 manufactured by Meier Vakuum Technik GMBH) for 5 min at 125° C. Each of the solar cell modules thus prepared has a dimension of 172×152 mm.

In E1 and E2, a 1.5 cm wide sealant strip made from CBS-1 or CBS-2, respectively, is placed around the outer periphery of the solar cell module. Thereafter, two 172 mm long aluminum frame bars and two 152 mm long aluminum frame bars are locked around the outer periphery of the solar cell module, which are covered by the sealant strip. The whole assembly is then heated in a 150° C. oven for 15 min to form the final framed solar cell module.

While certain of the preferred embodiments of the present invention have been described and specifically exemplified above, it is not intended that the invention be limited to such embodiments. Rather, it is to be understood that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

What is claimed is:

1. A framed solar cell module comprising:
(a) a platelike solar cell module comprising a solar cell element formed of one or a plurality of electrically interconnected solar cells;
(b) a frame body having a groove portion, into which the outer periphery of the solar cell module is fitted; and
(c) a sealant material so provided as to fill up a space between the outer periphery of the solar cell module and the groove portion of the frame body, the sealant material being formed of a cross-linkable blend composition comprising 10-90 wt % of an ionomer and 10-90 wt % of an ethylene copolymer, wherein the total wt % of all the components comprised in the cross-linkable composition is 100 wt %, and further wherein
(i) the ionomer is derived from a precursor acid copolymer consisting essentially of copolymerized units of ethylene, optionally up to 40 wt % of copolymerized units of a first olefin having a formula of CH₂═C(R¹)CO₂R², and 2-30 wt % of copolymerized units of a second olefin having a formula of CH₂═C(R³)COOH, wherein the total wt % of the copolymerized units comprised in the precursor acid copolymer is 100 wt %, wherein R¹ is hydrogen or an alkyl group, R² is an alkyl group, and R³ is hydrogen or an alkyl group, and wherein at least a portion of the carboxylic acid groups of the precursor acid copolymer is neutralized to form the ionomer, said ionomer comprising carboxylate groups and one or more cations;
(ii) the ethylene copolymer consists essentially of copolymerized units of ethylene, optionally up to 40 wt % of copolymerized units of the first olefin, and 3-15 wt % of copolymerized units of a third olefin having a formula of CH₂═C(R⁴)-D, wherein the total wt % of the copolymerized units comprised in the ethylene copolymer is 100 wt %, and wherein R⁴ is hydrogen or an alkyl group and -D is a moiety selected from the group consisting of —CO₂R⁵, —CO₂R⁶—R⁵, —R⁶—R⁵, —O—R⁵, and —R⁵; R⁵ is a moiety containing an epoxy group and R⁶ is an alkylene group; and
(iii) none of the first, second or third olefin is a dicarboxylic acid or a di-ester, mono-ester or anhydride of the dicarboxylic acid.

2. The framed solar cell module of claim 1, wherein the sealant material comprises a product of cross-linking the cross-linkable blend composition, and wherein in said product at least a portion of the carboxylic acid groups or carboxylate groups comprised in the ionomer are reacted with at least a portion of the epoxy groups comprised in the ethylene copolymer to form cross-links between the ionomer and the ethylene copolymer.

3. The framed solar cell module of claim 1, wherein the weight ratio of the ionomer and the ethylene copolymer comprised in the cross-linkable blend composition ranges from 80:20 to 20:80, or from 70:30 to 30:70; or from 60:40 to 40:60.

4. The framed solar cell module of claim 1, wherein, the first olefin is selected from the group consisting of methyl acrylate, methyl methacrylate, ethyl acrylate, ethyl methacrylate, butyl acrylate, and butyl methacrylate; or wherein the second olefin is an acrylic acid or a methacrylic acid; or wherein the moiety R⁵ is a glycidyl group, a 1,2-cyclohexenyl oxide group, or a 1,2-epoxy group.

5. The framed solar cell module of claim 1, wherein the precursor acid copolymer of the ionomer comprises 5-40 wt %, or 10-35 wt %, or 10-30 wt % of copolymerized units of the first olefin; or wherein the precursor acid copolymer of the ionomer comprises 5-20 wt % or 5-15 wt % of copolymerized units of the second olefin; or wherein the precursor acid copolymer of the ionomer has a melt flow rate of 5 g/10 min or higher, or 30 g/10 min or higher, or 30-500 g/10 min, as determined in accordance with ASTM D1238 at 190° C. and under a weight of 2.16 kg; or wherein 10-90%, or 15-60%, or 15-40% of the carboxylic acid groups of the precursor acid copolymer are neutralized; or wherein the one or more cations are selected from Na⁺ cations, Zn²⁺ cations, and a combination of Na⁺ and Zn²⁺ cations.

6. The framed solar cell module of claim 1, wherein the ionomer has a melt flow rate of 1 g/10 min or higher, or 2-500 g/10 min, or 4-500 g/10 min, as determined in accordance with ASTM D1238 at 190° C. and under a weight of 2.16 kg.

7. The framed solar cell module of claim 6, wherein the ionomer is a zinc ionomer that is derived from a precursor acid copolymer that is a copolymer of ethylene/methacrylic acid.

8. The framed solar cell module of claim 1, wherein the ethylene copolymer comprises 3-10 wt % or 4-7 wt % of copolymerized units of the third olefin; or wherein the ethylene copolymer comprise 5-40 wt %, or 10-40 wt %, or 20-40 wt %, or 20-35 wt % of copolymerized units of the first olefin; or wherein the ethylene copolymer has a melt flow rate of 5-300 g/10 min or 5-100 g/10 min, as determined in accordance with ASTM D1238 at 190° C. and under a weight of 2.16 kg.

9. The framed solar cell module of claim 8, wherein the ethylene copolymer is a copolymer of ethylene/n-butyl acrylate/glycidyl methacrylate.

10. The framed solar cell module of claim 1, wherein the frame body is formed of a metallic material or a plastic material.

11. A method for preparing the framed solar cell module of claim 1, comprising the steps of:
(a) providing a platelike solar cell module comprising a solar cell element formed of one or a plurality of electrically interconnected solar cells;
(b) providing a frame body having a groove portion;
(c) providing a sealant material formed of the cross-linkable blend composition; and
(d) attaching the outer periphery of the solar cell module into the inside of the groove portion of the frame body, with the sealant material filling up the space between the outer periphery of the solar cell module and the frame body, to obtain the framed solar cell module.

12. The method of claim 11, wherein step (d) comprises: (i) attaching a polymer strip formed of the sealant material around the outer periphery of the solar cell module; and (ii) attaching the outer periphery of the solar cell module, which is covered by the polymer strip, into the inside of the groove portion of the frame body.

13. The method of claim 11, wherein step (d) comprises: (i) attaching a polymer strip formed of the sealant material over the inside of the groove portion of the frame body; and (ii) attaching the outer periphery of the solar cell module into the inside of the groove portion of the frame body, which is covered by the polymer strip.

14. The method of claim 11, wherein step (d) comprises: (i) extrusion coating the sealant material around the outer periphery of the solar cell module; and (ii) attaching the outer periphery of the solar cell module, which is extrusion coated with the sealant material, into the inside of the groove portion of the frame body.

15. The method of claim 11, wherein step (d) comprises: (i) extrusion coating the sealant material over the inside of the groove portion of the frame body; and (ii) attaching the outer periphery of the solar cell module into the inside of the groove portion of the frame body, which is extrusion coated with the sealant material.

16. The method of claim 11, further comprising the step of (e) subjecting the framed solar cell module obtained in step (d) to curing at a temperature of 135° C. or higher, or 140° C.-180° C., with the curing duration being 5-60 minutes, or 5-30 minutes, or 5-20 minutes.

17. A method for preparing the framed solar cell module of claim 1, comprising the steps of:
(a) providing a platelike solar cell module comprising a solar cell element formed of one or a plurality of electrically interconnected solar cells;
(b) co-extruding a polymer composition and the cross-linkable blend composition to form a frame body, wherein the frame body has a groove portion and the inside layer of the groove portion is formed of the cross-linkable blend composition; and
(c) attaching the outer periphery of the solar cell module into the inside of the groove portion of the frame body.

18. The method of claim 17, further comprising the step of (d) subjecting the framed solar cell module obtained in step (c) to curing at a temperature of 135° C. or higher, or 140° C.-180° C., with the curing duration being 5-60 minutes, or 5-30 minutes, or 5-20 minutes.
